(19) United States
(12) Patent Application Publication
(10) Pub. No.: US 2009/0294922 A1
(43) Pub. Date: Dec. 3, 2009

(54) ORGANIC SILICON OXIDE FINE PARTICLE AND PREPARATION METHOD THEREOF, POROUS FILM-FORMING COMPOSITION, POROUS FILM AND FORMATION METHOD THEREOF, AND SEMICONDUCTOR DEVICE

(76) Inventors: Yoshitaka Hamada, Nllgata-ken (JP); Fujio Yagihashi, Niigata-ken (JP); Takeshi Asano, Niigata-ken (JP); Hideo Nakagawa, Shiga (JP); Masaru Sasago, Osaka (JP)

Correspondence Address: MYERS BIGEL SIBLEY & SAJOVEC, PO BOX 37428, RALEIGH, NC, 27627, US

(21) Appl. No.: 12/472,645

(22) Filed: May 27, 2009

(30) Foreign Application Priority Data
May 30, 2008 (JP) 2008-142343

(51) Int. Cl. H01L 23/58; H01L 21/47; C07F 7/08; B32B 9/00

(52) U.S. Cl. 257/632; 438/781; 106/287.13; 428/405; 257/E21.489

(57) ABSTRACT

Provided is an organic silicon oxide fine particle capable of satisfying an expected dielectric constant and mechanical strength and having excellent chemical stability for obtaining a high-performance porous insulating film. More specifically, provided is an organic silicon oxide fine particle comprising a core comprising an inorganic silicon oxide or a first organic silicon oxide containing an organic group having a carbon atom directly attached to a silicon atom and, and a shell on or above an outer circumference of the core, the shell comprising a second organic silicon oxide different from the first organic silicon oxide which the second organic silicon has been formed by hydrolysis and condensation, in the presence of a basic catalyst, of a shell-forming component comprising an organic-group-containing hydrolyzable silane containing an organic group having a carbon atom directly attached to a silicon atom or a mixture of the organic-group-containing hydrolyzable silane and an organic-group-free hydrolyzable silane not having the organic group, wherein a ratio [C]/[Si] is 0 or greater but less than 1 in the core and 1 or greater 1 in the shell wherein [C] represents the number of all the carbon atoms and [Si] represents the number of all the silicon atoms.

### CROSS-RELATED APPLICATIONS

This application claims priority from Japanese Patent Application No. 2008-142343; filed May 30, 2008, the disclosure of which is incorporated herein by reference in its entirety.

### BACKGROUND OF THE INVENTION

1. Field of the Invention

The present invention relates to an organic silicon oxide fine particle which can be formed into a porous film excellent in dielectric properties, mechanical strengths and a chemical stability, a film-forming composition, a method for preparing a porous film and a porous film prepared thereby, and a semiconductor device comprising the porous film therein.

2. Description of the Related Art

In the fabrication of semiconductor integrated circuits, as their integration degree becomes higher, an increase in interconnect delay time due to an increase in interconnect capacitance, which is a parasitic capacitance between metal interconnects, prevents their performance enhancement. The interconnect delay time is called an RC delay which is in proportion to the product of the electric resistance of metal interconnects and the static capacitance between interconnects. In order to reduce the interconnect delay time, it is necessary to reduce the resistance of metal interconnects or to reduce the capacitance between interconnects. The reduction in the resistance of an interconnect metal or interconnect capacitance can prevent even a highly integrated semiconductor device from causing an interconnect delay, which enables size reduction and high speed operation of it and moreover, minimization of power consumption.

In order to reduce the resistance of metal interconnects, semiconductor device structures using copper as metal interconnects have recently replaced those using conventional interconnects made of aluminum. Use of copper interconnects alone, however, has limits in accomplishing performance enhancement so that reduction in the interconnect capacitance is an urgent necessity for further performance enhancement of semiconductor devices.

One method for reducing interconnect capacitance is to reduce the dielectric constant of an interlayer insulating film disposed between metal interconnects. As such a low-dielectric-constant insulating film, use of a porous film instead of a conventionally used silicon oxide film has been studied. In particular, since a porous film is only available in practice as a material suited as an interlayer insulating and having a dielectric constant not greater than 2.5, various methods for forming a porous film have been proposed. When an interlayer insulating film is made porous, however, reduction in mechanical strength and adsorption of water are likely to deteriorate the film so that reduction in dielectric constant (k) by introduction of pores into the film and maintenance of sufficient mechanical strength and hydrophobicity are serious problems that need to be overcome.

An organic silicon oxide film having enhanced mechanical strength can be obtained, for example, by increasing the proportion of tetrafunctional silicon units as a silicon unit constituting the film, thereby constructing a densely crosslinked siloxane structure to form a hard particle. In practice, a film produced by plasma polymerization of tetrafunctional TEOS shows strength as high as 80 GPa in bulk form (form having no porosity). When a film is prepared from a hydrolysis condensate of a trifunctional alkoxysilane having a methyl group, on the other hand, it shows strength of 20 GPa or less even in bulk form (“Low-k Materials and Process Integration after the 65 nm and 45 nm Generations”, by Eiki SHIBATA, from proceedings of a lecture held by Electronic Journal on Apr. 18, 2006, at Ochanomizu, Tokyo). Even when pores are introduced into the above films to decrease their dielectric constant, a relationship in the strength in bulk form still remains. It is well-known that as the proportion of tetrafunctional units becomes larger, high strength can be achieved more easily.

With regard to chemical properties, the binding energy itself of a Si—O bond is greater than that of a Si—C bond so that the former gives a structure resistant to heat decomposition. Difference in reactivity with a chemical substance such as washing fluid is, on the other hand, attributable to a large difference in polarity between the Si—C bond and the Si—O bond and the Si—O bond having a greater polarity is susceptible to the attack (nucleophilic attack) of the chemical substance. Similarly, comparison in polarity between tetrafunctional silicon and trifunctional silicon has revealed that an electron density at the center of tetrafunctional silicon lowers (greater in δ+) with increase of the number of Si—O bonds having a large polarity and it is susceptible to nucleophilic attack.

Damage in an ashing or wet etching process extends from a hydrophilized surface of an insulating film, and the dielectric constant of the film inevitably increases by the nucleophilic attack to Si having a Si—O bond. Introduction of a non-polar organic component typified by an alkyl group, can impart organic component-derived hydrophobicity to the surface of the film so that the resistance against damage is expected to enhance.

When a porous silica film is used as an interlayer insulating film of a semiconductor device, process damage in an etching or washing step poses a problem. In particular, hydrophilization of the surface of the porous silica film after treatment with a washing fluid and moisture absorption resulting therefrom lead to reduction in the reliability of the semiconductor device. There is therefore a demand for overcoming such a problem.

It has been recognized that susceptibility of a CVD-LK film (LK is an abbreviation of low-k) to such a process damage tends to become smaller with an increase in its carbon content. Also in an LK film of an application type, an increase in carbon content by introducing a carbosilane skeleton is under study (JP 2007-262257A).

### SUMMARY OF THE INVENTION

An object of the present invention is to provide an organic silicon oxide fine particle which is prepared by using an industrially preferable material in order to obtain a high-performance porous insulating film formed by the application and can be formed into a porous film capable of satisfying an expected dielectric constant and mechanical strength and excellent in chemical stability, and also to provide a film-forming composition containing the particle, a method for forming a porous film, and a porous film formed thereby.

Another object of the present invention is to provide a high-performance and high-reliability semiconductor device having the porous film prepared by such an advantageous material.

As described above, when a film is viewed as a whole, there is a trade-off relationship between maintenance of mechanical strength and improvement in chemical stability. The chemical stability is obtained by incorporating a substituent, such as alkyl or alkylene, containing carbon having a direct bond to silicon in a hydrolyzable silane compound or compounds for obtaining an organic silicon oxide fine particle to be used as a film-forming material, thereby increasing the carbon content of the compound. Simple blending of a material having high mechanical strength and a material having high chemical stability cannot result in the formation of the expected material.

The present inventors therefore made the following working hypothesis for improving the performance of a porous film-forming coating solution making use of an organic silicon oxide fine particle.

According to their hypothesis, it is preferred to place parts having respective functions only at required positions thereof in order to avoid resulting in simple averages of physical properties, and moreover, it is preferred to use a material in which only necessary amounts of potentially necessary parts are arranged at proper positions in order to achieve such controlled arrangement by using a uniform coating solution. It is possible to achieve such a particular arrangement by using different materials for a core portion of the silica particle and an outer circumferential film covering the outer circumference of the core portion, respectively. A film in which a material constituting a core portion and a material constituting an outer peripheral film have been arranged regularly can be obtained only by applying a coating solution of such an organic silicon oxide fine particle to a substrate. A composite type organic silicon oxide fine particle having different materials for core and shell, respectively, is thus considered to be useful.

Further, the present inventors have thought that a film formed by using a composite type organic silicon oxide fine particle where a material having high mechanical strength is used for the core and another material providing chemical stability is used for the shell, has high hydrophobicity at an interface contiguous to the outside so that it can have chemical stability and at the same time, cores are arranged at intervals formed by the shells to achieve high mechanical strength, while preventing uneven presence of a material having low mechanical strength. Moreover, the present inventors have thought that when the shells are soft, contact areas of the organic silicon oxide fine particles become wide, interparticle bonds are formed by baking while maintaining the wide contact areas, and formation of a matrix having high mechanical strength can be expected.

In the surface modification for changing the quality of silica particles or zeolite particles, a method of modifying the side chain thereof having a mercapto group in order to give a bond formation capacity to a polymerizable functional group is known (JP 10-81839A/1998). Since this method gives reactivity by offering freedom to the surface-modified functional group, it is preferable not to raise a condensation degree of the silane having a substituent. Accordingly, the surface modification in JP 10-81839A/1998 is performed in the presence of an acid catalyst. On the other hand, from the standpoint of preventing silicon from undergoing nucleophilic attack in order to overcome the problem to be solved by the invention, the outer peripheral film is required to be crosslinked densely and thereby have a function of preventing invasion of a nucleophilic species into the inside of the particles. The particles obtained using an acid catalyst are therefore not preferred.

The present inventors disclose a method of modifying an organic silicon oxide fine particle with a crosslinkable side chain in the presence of a basic catalyst, thereby improving an interparticle bonding power (JP 2005-216895A). This method uses a basic catalyst for freezing the activity of the crosslinking group, but it does not include a concept of imparting chemical stability to the particles by surface modification.

The present inventors have carried out an intensive investigation based on the above hypothesis. As a result, they have succeeded in forming a porous film having both mechanical strength and chemical stability by using a porous film-forming composition containing a composite type silica fine particle. The composite type silica fine particle has been prepared by forming a core of an organic silicon oxide fine particle from a material comprising a tetravalent hydrolyzable silane as a main component in the presence of a basic catalyst, and then by forming a shell covering the outer circumference of the core from a material comprising a trivalent hydrolyzable silane having a hydrocarbon substituent as a main component. Moreover, they have found a method for preparing a coating composition capable of providing a film having improved physical properties suited for use even in a semiconductor fabrication process, leading to the completion of the invention. In this technology, not only an inorganic or organic silica fine particle but also a zeolite fine particle can be used as the core. Use of the zeolite fine particle can enhance the strength of the core further.

According to the invention, there is thus provided an organic silicon oxide fine particle comprising:

a core comprising an inorganic silicon oxide or a first organic silicon oxide containing an organic group having a carbon group directly attached to a silicon atom; and

a shell on or above an outer circumference of the core, the shell comprising a second organic silicon oxide different from the first organic silicon oxide

wherein the second organic silicon oxide has been formed by hydrolysis and condensation of a shell-forming component comprising an organic-group-containing hydrolyzable silane containing an organic group having a carbon atom attached directly to a silicon atom or a mixture of the organic-group-containing hydrolyzable silane and an organic-group-free hydrolyzable silane not containing the organic group in the presence of a basic catalyst;

wherein a ratio of [C]/[Si] is 0 or greater but less than 1 in the core and 1 or greater in the shell wherein [C] represents the total number of carbon atoms contained by the organic group of the first organic silicon oxide in the core or by the organic group of the second organic silicon oxide in the shell and [Si] represents the total number of silicon atoms contained in the core or in the shell.

According to the invention, there is also provided a method for preparing an organic silicon oxide fine particle, comprising steps of:

Hydrolyzing and condensing, in the presence of a basic catalyst and in water or a mixed solution of water and alcohol, a core-forming component comprising a first organic-group-containing hydrolyzable silane containing an organic group having a carbon atom directly attached to a silicon atom or a first organic-group-free hydrolyzable silane not containing the organic group to form a core

wherein a ratio of [C]/[Si] is 0 or greater but less than 1 wherein [C] represents the number of all the carbon atoms contained by the organic group and [Si] represents the number of all the silicon atoms contained by the core-forming component; and

adding, to the reaction mixture thus obtained, a shell-forming component comprising a second organic-group-containing hydrolyzable silane containing an organic group having a carbon atom directly attached to a silicon atom or a mixture of the second organic-group-containing hydrolyzable silane and a second organic-group-free hydrolyzable silane to form a shell

wherein a ratio of [C]/[Si] is 1 or greater wherein [C] represents the number of all the carbon atoms contained by the organic group in the second organic-group-containing hydrolyzable silane and [Si] represents the number of all the silicon atoms contained by the shell-forming component.

According to the invention, there are also provided a porous film-forming composition comprising at least an organic silicon oxide fine particle and an organic solvent; and a porous film formed by using the porous film-forming composition.

According to the invention, there is also provided a method for forming a porous film, comprising steps of:

applying the porous film-forming composition to form a film, and

subjecting the film to heat, or an electron beam or light.

According to the invention, there is also provided a semiconductor device comprising the porous film as an insulating film.

For example, a film prepared from methyltrimethoxysilane by CVD has low dielectric properties comparable to those of a zeolite film, but has deteriorated mechanical strength inevitably. When a film is formed without causing deterioration in mechanical strength, on the other hand, it has a problem in chemical stability as described above. In forming a film having a practically effective low dielectric constant, it is a fundamental problem how to use an organic silicon oxide material as a material of the film.

According to the composite type organic silicon oxide fine particle of the invention, high mechanical strength can be achieved by setting a [C]/[Si] ratio of the core at 0 or greater but less than 1, 0≦[C]/[Si] (in core) <1, to keep a dielectric property as effectively low as possible and at the same time, by setting a Si—O—Si bond density high; while chemical stability against a washing fluid or the like can be achieved by setting a [C]/[Si] ratio of the shell at 1 or greater, 1≦[C]/[Si] (in shell), and by forming the shell through condensation in the presence of a basic catalyst to form a hydrophobic skin having a high degree of condensation. Since the shell has a [C]/[Si] ratio of 1 or greater, the shell has spatially high freedom which facilitates deformation and is effective for increasing a spatial interaction area between particles in the film formed.

According to the method for preparing an organic silicon oxide fine particle of the invention, an organic silicon oxide fine particle comprising a shell having high chemical stability on the outer circumference of a core having high mechanical strength can be prepared easily.

According to the porous film-forming composition of the invention, a porous film having both high mechanical strength and high chemical stability can be prepared easily.

Since the porous film of the invention has high mechanical strength and high chemical stability, it is suited for use in applications required to satisfy them simultaneously, particularly for a low dielectric constant film to be used in a semiconductor device.

According to the method for forming a porous film of the invention, comprising steps of applying the porous film-forming composition and heating, a porous film having high mechanical strength and high chemical stability can be prepared.

The semiconductor device according to the invention has high reliability because it is produced using the porous film as an insulating film.

### DETAILED DESCRIPTION OF THE INVENTION

The present invention now will be described more fully hereinafter in which embodiments of the invention are provided with reference to the accompanying drawings. This invention may, however, be embodied in many different forms and should not be construed as limited to the embodiments set forth herein; rather, these embodiments are provided so that this disclosure will be thorough and complete, and will fully convey the scope of the invention to those skilled in the art.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise.

Unless otherwise defined, all technical and scientific terms used herein have the same meaning as commonly understood by one of ordinary skill in the art to which this invention belongs.

Hereinafter, preferred embodiments of the present invention will be described. However, it is to be understood that the present invention is not limited thereto.

The invention relates to an organic silicon oxide fine particle comprising a core containing a silicon oxide material excellent in mechanical strength because of low or no carbon content and a shell containing a silicon oxide material highly hydrophobic because of a high condensation degree and high carbon content. Since the materials constituting the core and shell are different from each other, a film formed using them has a micro regular arrangement. An object of the invention is therefore to allow the core and the shell to exhibit desirable physical properties, respectively, compared with use of these materials simply as a mixture or bonded materials.

The organic silicon oxide fine particles of the invention may have an average particle size of preferably 50 nm or less, more preferably 5 nm or less. The organic silicon oxide fine particles having a particle size exceeding 50 nm may generate striation upon spin coating and thus may have an adverse effect. The particle size of the fine particles can be measured using, for example, a submicron particle size distribution analyzer “N4Plus” (trade name; product of Coulter), and its lower measurement limit is 2 nm. There is no effective means for measuring the particle sizes less than 2 nm. The preferable lower limit of the particle size can therefore be considered theoretically as follows. When the average particle size of the core is less than 0.5 nm, a proportion of a shell component which will be described later may become too high relative to that of the core component so that there may be shortage in physical strength for which the core is responsible. The thickness of the shell may be preferably from 0.025 to 0.5 nm, more preferably from 0.05 to 0.2 nm. The shell having a thickness less than 0.025 nm may not sufficiently cover the surface of the core and therefore cannot achieve expected chemical stability. The thickness exceeding 0.5 nm, on the other hand, may cause lack of physical strength because the proportion of the shell component becomes too high relative to that of the core component.

When the carbon content increases, as is apparent from the above comparison between a bulk film derived from tetraethoxysilane and a bulk film derived from methyl-substituted alkoxysilane, the number of Si—O—Si bonds in a certain volume decreases as a result of the substitution with the alkyl group and at the same time, the space occupied by the alkyl group has therein no bond with another atom so that freedom of a silicon oxide skeleton occupying the space increases, leading to a reduction in dielectric constant. However, it also means deterioration in mechanical strength. By using a [C]/[Si] ratio of a material, a ratio of the number of all the carbon atoms contained in all the substituents bonded to silicon via a Si—C bond to the number of all the silicon atoms, the mechanical strength of the material can be discussed.

When the [C]/[Si] ratio of the organic silicon oxide material is less than 1, it contains a silicon atom having the maximum number of Si—O—Si bonds, that is, it contains a silicon atom having all of the four bonds connected with oxygen atoms. Thus, a smaller ratio means higher strength. On the other hand, a large [C]/[Si] ratio of the silicon oxide material obviously means high hydrophobicity.

The organic silicon oxide fine particles being found by the present inventors and having both mechanical strength and chemical stability have a structure in which a shell having the [C]/[Si] ratio of 1 or greater and being responsible for chemical stability covers, in a highly condensed form, a hard core having the [C]/[Si] ratio less than 1 and being responsible for mechanical strength.

As the core, an inorganic silicon oxide or an organic silicon oxide containing an organic group having a carbon atom directly attached to the silicon atom can be used. For example, not only inorganic or organic silica fine particles but also zeolite fine particles can be employed. Employment of the latter enables further strength enhancement of the core. Zeolite fine particles can be formed by a hydrothermal reaction using tetraethoxysilane as a raw material in the presence of tetrapropylammonium as a catalyst.

For the core, a material contributing to high mechanical strength in spite of containing an organic material for achieving a low dielectric constant should be selected. It may be preferred to prepare organic silicon oxide fine particle to be used for the core by using a mixture of hydrolyzable silane compounds containing a compound represented by the following formula (1):

Si(OR¹)₄ (1)

wherein R¹s may be the same or different and each independently represents a linear or branched C₁₋₄ alkyl group. The compound represented by formula (1) can provide organic silicon oxide fine particles having a higher Si—O—Si density, among the conventionally employed organic silicon oxide fine particles.

The hydrolyzable silane compound having a hydrocarbon side-chain and being used in combination may be preferably a compound represented by the following formula (2):

R²ₙSi(OR³)₄₋ₙ (2)

wherein R²s may be the same or different and each independently represents a linear or branched C₁₋₄ alkyl group and R³s may be the same or different and each independently represents a linear or branched C₁₋₄ alkyl group, and n stands for an integer from 1 to 3.

Specific examples of the silane compound represented by the formula (1) and preferably employed in the invention may include, but not limited to, tetramethoxysilane, tetraethoxysilane, tetrapropoxysilane, tetrabutoxysilane, tetraisopropoxysilane, tetraisobutoxysilane, triethoxymethoxysilane, tripropoxymethoxysilane, tributoxymethoxysilane, trimethoxyethoxysilane, trimethoxypropoxysilane, and trimethoxybutoxysilane.

Examples of the silane compound represented by the formula (2) may include methyltrimethoxysilane, methyltriethoxysilane, methyltri-n-propoxysilane, methyltri-i-propoxysilane, methyltri-n-butoxysilane, methyltri-s-butoxysilane, methyltri-i-butoxysilane, methyltri-t-butoxysilane, ethyltrimethoxysilane, ethyltriethoxysilane, ethyltri-n-propoxysilane, ethyltri-i-propoxysilane, ethyltri-n-butoxysilane, ethyltri-s-butoxysilane, ethyltri-i-butoxysilane, ethyltri-t-butoxysilane, n-propyltrimethoxysilane, n-propyltriethoxysilane, n-propyltri-n-propoxysilane, n-propyltri-i-propoxysilane, n-propyltri-n-butoxysilane, n-propyltri-s-butoxysilane, n-propyltri-i-butoxysilane, n-propyltri-t-butoxysilane, i-propyltrimethoxysilane, i-propyltriethoxysilane, i-propyltri-n-propoxysilane, i-propyltri-i-propoxysilane, i-propyltri-n-butoxysilane, i-propyltri-s-butoxysilane, i-propyltri-i-butoxysilane, i-propyltri-t-butoxysilane, n-butyltrimethoxysilane, n-butyltriethoxysilane, n-butyltri-n-propoxysilane, n-butyltri-i-propoxysilane, n-butyltri-n-butoxysilane, n-butyltri-s-butoxysilane, n-butyltri-i-butoxysilane, n-butyltri-t-butoxysilane, i-butyltrimethoxysilane, i-butyltriethoxysilane, i-butyltri-n-propoxysilane, i-butyltri-i-propoxysilane, i-butyltri-n-butoxysilane, i-butyltri-s-butoxysilane, i-butyltri-i-butoxysilane, i-butyltri-t-butoxysilane, s-butyltrimethoxysilane, s-butyltriethoxysilane, s-butyltri-n-propoxysilane, s-butyltri-i-propoxysilane, s-butyltri-n-butoxysilane, s-butyltri-s-butoxysilane, s-butyltri-i-butoxysilane, s-butyltri-t-butoxysilane, t-butyltrimethoxysilane, t-butyltriethoxysilane, t-butyltri-n-propoxysilane, t-butyltri-i-propoxysilane, t-butyltri-n-butoxysilane, t-butyltri-s-butoxysilane, t-butyltri-i-butoxysilane, t-butyltri-t-butoxysilane, dimethyldimethoxysilane, dimethyldiethoxysilane, dimethyldi-n-propoxylsilane, dimethyldi-i-propoxysilane, dimethyldi-n-butoxysilane, dimethyldi-s-butoxysilane, dimethyldi-i-butoxysilane, dimethyldi-t-butoxysilane, diethyldimethoxysilane, diethyldiethoxysilane, diethyldi-n-propoxylsilane, diethyldi-i-propoxysilane, diethyldi-n-butoxysilane, diethyldi-s-butoxysilane, diethyldi-i-butoxysilane, diethyldi-t-butoxysilane, di-n-propyldimethoxysilane, di-n-propyldiethoxysilane, di-n-propyldi-n-propoxylsilane, di-n-propyldi-i-propoxysilane, di-n-propyldi-n-butoxysilane, di-n-propyldi-s-butoxysilane, di-n-propyldi-i-butoxysilane, di-n-propyldi-t-butoxysilane, di-i-propyldimethoxysilane, di-i-propyldiethoxysilane, di-i-propyldi-n-propoxylsilane, di-i-propyldi-i-propoxysilane, di-i-propyldi-n-butoxysilane, di-i-propyldi-s-butoxysilane, di-i-propyldi-i-butoxysilane, di-i-propyldi-t-butoxysilane, di-n-butyldimethoxysilane, di-n-butyldiethoxysilane, di-n-butyldi-n-propoxylsilane, di-n-butyldi-i-propoxysilane, di-n-butyldi-n-butoxysilane, di-n-butyldi-s-butoxysilane, di-n-butyldi-i-butoxysilane, di-n-butyldi-t-butoxysilane, di-i-butyldimethoxysilane, di-i-butyldiethoxysilane, di-i-butyldi-n-propoxylsilane, di-i-butyldi-i-propoxysilane, di-i-butyldi-n-butoxysilane, di-i-butyldi-s-butoxysilane, di-i-butyldi-i-butoxysilane, di-i-butyldi-t-butoxysilane, di-s-butyldimethoxysilane, di-s-butyldiethoxysilane, di-s-butyldi-n-propoxylsilane, di-s-butyldi-i-propoxysilane, di-s-butyldi-n-butoxysilane, di-s-butyldi-s-butoxysilane, di-s-butyldi-i-butoxysilane, di-s-butyldi-t-butoxysilane, di-t-butyldimethoxysilane, di-t-butyldiethoxysilane, di-t-butyldi-n-propoxylsilane, di-t-butyldi-i-propoxysilane, di-t-butyldi-n-butoxysilane, di-t-butyldi-s-butoxysilane, di-t-butyldi-i-butoxysilane, di-t-butyldi-t-butoxysilane, trimethylmethoxysilane, trimethylethoxysilane, trimethyl-n-propoxysilane, trimethyl-i-propoxysilane, trimethyl-n-butoxysilane, trimethyl-s-butoxysilane, trimethyl-i-butoxysilane, trimethyl-t-butoxysilane, triethylmethoxysilane, triethylethoxysilane, triethyl-n-propoxylsilane, triethyl-i-propoxysilane, triethyl-n-butoxysilane, triethyl-s-butoxysilane, triethyl-i-butoxysilane, triethyl-t-butoxysilane, tri-n-propylmethoxysilane, tri-n-propylethoxysilane, tri-n-propyl-n-propoxysilane, tri-n-propyl-i-propoxysilane, tri-n-propyl-n-butoxysilane, tri-n-propyl-s-butoxysilane, tri-n-propyl-i-butoxysilane, tri-n-propyl-t-butoxysilane, tri-i-propylmethoxysilane, tri-i-propylethoxysilane, tri-i-propyl-n-propoxylsilane, tri-i-propyl-i-propoxysilane, tri-i-propyl-n-butoxysilane, tri-i-propyl-s-butoxysilane, tri-i-propyl-i-butoxysilane, tri-i-propyl-t-butoxysilane, tri-n-butylmethoxysilane, tri-n-butylethoxysilane, tri-n-butyl-n-propoxylsilane, tri-n-butyl-i-propoxysilane, tri-n-butyl-n-butoxysilane, tri-n-butyl-s-butoxysilane, tri-n-butyl-i-butoxysilane, tri-n-butyl-t-butoxysilane, tri-i-butylmethoxysilane, tri-i-butylethoxysilane, tri-i-butyl-n-propoxylsilane, tri-i-butyl-i-propoxysilane, tri-i-butyl-n-butoxysilane, tri-i-butyl-s-butoxysilane, tri-i-butyl-i-butoxysilane, tri-i-butyl-t-butoxysilane, tri-s-butylmethoxysilane, tri-s-butylethoxysilane, tri-s-butyl-n-propoxylsilane, tri-s-butyl-i-propoxysilane, tri-s-butyl-n-butoxysilane, tri-s-butyl-s-butoxysilane, tri-s-butyl-i-butoxysilane, tri-s-butyl-t-butoxysilane, tri-t-butylmethoxysilane, tri-t-butylethoxysilane, tri-t-butyl-n-propoxylsilane, tri-t-butyl-i-propoxysilane, tri-t-butyl-n-butoxysilane, tri-t-butyl-s-butoxysilane, tri-t-butyl-i-butoxysilane and tri-t-butyl-t-butoxysilane.

According to the method of the invention, one or more of the silane compounds represented by the formula (1) may be mixed with one or more of the silane compounds represented by the formula (2).

Addition of the hydrolyzable silane compound represented by the formula (2) in an adequate amount may be preferred because a porous film thus obtained tends to have a reduced dielectric constant. When a mixture of the silane compounds represented by the formulas (1) and (2) is used as a raw material for the synthesis of the core, the Si—O—Si density inside the core may be preferably higher in order to achieve sufficient strength. One or more silane compounds represented by the formula (1) may be preferably 50 mol % or greater of the silane compound or compounds subjected to hydrolysis and condensation for obtaining the core; one or more silane compounds represented by the formula (1) may be preferably 95 mol % or less of the silane compound or compounds subjected to hydrolysis and condensation for obtaining the core in order to produce an introduction effect of an organic group. One or more silane compounds represented by the formula (2) may be preferably 5 mol % or greater but not greater than 50 mol % of the silane compound or compounds subjected to hydrolysis and condensation for obtaining the core.

Organic silicon oxide fine particles to be the core can be obtained by hydrolysis and condensation of the hydrolyzable silane in the presence of an acid or basic catalyst. The core may be preferably obtained by hydrolysis and condensation of the hydrolyzable silane in the presence of a basic catalyst because the basic catalyst can raise a density (condensation degree) of Si—O—Si bonds, thereby achieving high mechanical strength.

Examples of the acid catalyst may include inorganic acid such as hydrochloric acid, sulfuric acid and nitric acid; sulfonic acid such as methanesulfonic acid, benzenesulfonic acid, p-toluenesulfonic acid and trifluoromethanesulfonic acid; organic acid such as formic acid, acetic acid, propionic acid, oxalic acid, malonic acid, fumaric acid, maleic acid, tartaric acid, citric acid and malic acid; and phosphoric acid.

The amount of the acid catalyst may be preferably from 1 to 50 mol % based on the total amount (number of moles) of the hydrolyzable silane compound or compounds.

Many compounds such as alkali metal hydroxide, organic ammonium hydroxide and amine are known as the basic catalysts. They may be used singly or in combination. Specific examples of the preferred compounds may include alkali metal hydroxide such as lithium hydroxide, sodium hydroxide, potassium hydroxide and cesium hydroxide; ammonium salt such as tetramethylammonium hydroxide, choline, tetraethylammonium hydroxide, tetrapropylammonium hydroxide, tetrabutylammonium hydroxide, tetrapentylammonium hydroxide, and tetrahexylammonium hydroxide; and amine such as DBU (1,8-diazabicyclo[5.4.0]undec-7-ene), DABCO (1,4-diazabicyclo[2.2.2]octane), triethylamine, diethylamine, pyridine, piperidine, piperazine and morpholine.

The basic catalyst may be used in an amount of preferably from 1 to 50 mol %, more preferably from 5 to 30 mol %, still more preferably from 10 to 20 mol % based on the total amount (the number of moles of silicon atoms) of the hydrolyzable silane compound or compounds. Excessively large amounts of the catalyst may make it difficult to obtain a low k film because growth of organic silicon oxide fine particles is inhibited and they do not grow sufficiently. On the other hand, excessively small amounts may make it impossible to obtain intended strength because of insufficient condensation of siloxane.

Fine particles having higher mechanical strength can be obtained, for example, by using the following hydrophobic quaternary ammonium hydroxide and the hydrophilic quaternary ammonium hydroxide in combination as the basic catalyst.

The hydrophilic basic catalyst may be alkali metal hydroxide or quaternary ammonium hydroxide represented by the following formula (3):

(R⁴)₄N⁺OH⁻ (3)

wherein R⁴s may be the same or different and each independently represents a C₁₋₂ hydrocarbon group which may contain an oxygen atom, and the cationic moiety [(R⁴)₄N⁺] satisfies the following equation (A):

(N+O)/(N+O+C)≧1/5 (A)

wherein N, O, and C are the number of nitrogen, oxygen and carbon atoms contained by the cationic moiety, respectively.

The hydrophobic basic salt may be preferably a compound represented by the following formula (4):

(R⁵)₄N⁺OH⁻ (4)

wherein R⁵ may be the same or different and each independently represents a linear or branched C₁₋₈ alkyl group with the proviso that R⁵s do not represents a methyl group simultaneously, and the cationic moiety[(R⁵)₄N⁺] satisfies the following equation (B):

(N+O)/(N+O+C)<1/5 (B)

wherein N, O, and C are the number of nitrogen, oxygen and carbon atoms contained by the cationic moiety, respectively.

The organic silicon oxide fine particles prepared in such a manner show higher strength compared with those prepared in the conventional manner.

When condensation is performed using the hydrophobic basic catalyst and the hydrophilic basic catalyst in combination, the hydrophilic basic catalyst may be added preferably in an amount of 0.2 to 2.0 moles per mol of the hydrophobic basic catalyst. A total amount of the hydrophobic basic catalyst and the hydrophilic basic catalyst may be similar to that of said basic catalyst and be preferably from 1 to 50 mol %, more preferably from 3 to 30 mol %, still more preferably from 5 to 20 mol % based on the total amount (the number of moles) of the hydrolyzable silane compound or compounds.

Further, the hydrolysis and condensation reaction of the hydrolyzable silane requires addition of water for hydrolysis and an amount of water to be added to the reaction system may be preferably from 0.5 to 100 times the mole, more preferably from 1 to 10 times the mole necessary for hydrolyzing the silane compound or compounds completely.

When the hydrolyzable silane compound or compounds are subjected to hydrolysis and condensation to obtain a polymer solution, the reaction system may contain, in addition to water, a solvent such as alcohol corresponding to the alkoxy group of the silane compound or compounds. Examples may include methanol, ethanol, isopropyl alcohol, butanol, propylene glycol monomethyl ether, propylene glycol monopropyl ether, propylene glycol monopropyl ether acetate, ethyl lactate and cyclohexanone. The solvent other than water may be added in an amount of preferably from 0.1 to 500 times the weight, more preferably from 1 to 100 times the weight of the silane compound or compounds.

The hydrolysis and condensation reaction of silane may be performed under the conditions employed for the conventional hydrolysis and condensation reaction. The reaction temperature may be set to fall within a range of usually from 0° C. to the boiling point of alcohol produced by the hydrolysis and condensation, preferably from room temperature to 80° C.

In a more convenient reaction method, silica fine particles may form and grow by adding the hydrolyzable silane compound or compounds directly or after dissolved in the above solvent to an aqueous solution of the basic catalyst adjusted to the above reaction temperature or in some cases, to a reaction mixture obtained by mixing the aqueous solution with the organic solvent. The addition may be usually dropwise addition or intermittent addition and addition time may be usually from 10 minutes to 24 hours, more preferably from 30 minutes to about 8 hours.

Then, a formation reaction of the shell portion, which will be described in detail later, can be conducted successively. Formation of the shell, on the core comprising the inorganic or organic silica, may be started after a so-called aging reaction, that is, maintenance of conditions under which the hydrolysis and condensation reaction proceeds for from 5 minutes to 4 hours, more preferably from 10 minutes to 1 hour after completion of the addition of the hydrolyzable silane compound or compounds for the formation of the core portion. It is also possible to change the composition continuously by carrying out the reaction while gradually changing the composition of the raw material from that for forming the core to that for forming the shell, or carrying out the reaction while partially overlapping the raw material for the core with the raw material for the shell.

Next, a shell for covering the outer circumference of the organic silicon oxide fine particles serving as the core is formed.

In order to improve the physical properties of the core, that is, high mechanical strength but low chemical stability due to high hydrophilicity, a material capable of imparting high hydrophobicity to the core having such physical properties is used as the material of the shell. The shell material capable of imparting hydrophobicity is available by using, for shell formation, a single substance or mixture of a hydrolyzable silane having a [C]/[Si] ratio satisfying the following equation: [C]/[Si]≧1, wherein [C] and [Si] respectively represent the number of all the carbon atoms and the number of all the silicon atoms contained by all the substituents connected to silicon via an inherent Si—C bond. Another expected effect may be that the shell is used for giving deformability to the surface of the particles for the purpose of widening the contact area and thereby enhancing the interparticle bonds during film formation. This means that a material capable of bringing the deformable surface to the core may be used for the shell.

As described above, after completion of the formation of the core, or after the aging step in some cases, it may be preferred to carry out the shell formation successively. When the core is isolated or it is left to stand for a long period of time, aggregation of core fine particles may possibly occur. The silanol group on the surface of the fine particles is very active just after preparation of the core fine particles so that a shell having a high density can be obtained by starting the shell formation immediately without changing the reaction conditions or immediately after re-adjustment of the reaction conditions, whereby the material for forming the shell efficiently reacts with the surface of the core fine particles. It may be also effective for suppressing the generation of new fine particles composed only of the material for forming the shell.

A shell can be formed on the surface of core zeolite by adding dropwise a solution containing the raw material for the shell formation to the zeolite fine particle solution of the core successively after preparation of the core by the above zeolite preparation process. During the formation of shell, an alcohol solvent may be added as needed or a basic catalyst having high hydrophilicity may be added further. When gelation occurs during the shell-forming process, addition of alcohol can prevent gelation effectively. The basic catalyst having high hydrophilicity is effective for forming a shell having a high crosslink density and high chemical stability.

When organic silicon oxide particles obtained using the acid catalyst are used as the core, the catalyst system should be changed from an acid to a base for obtaining a shell having a high density which can bring high chemical stability.

When organic silicon oxide particles obtained using the base catalyst are used as the core, alkoxysilane as a raw material for formation of the shell can form the shell without substantial re-adjustment of the reaction mixture such as addition of a new catalyst. In particular, a catalyst design for obtaining a core having high mechanical strength are same as a catalyst design for obtaining a shell having a high crosslink density which can bring high chemical stability so that it is preferred to successively add dropwise the shell-forming material to the reaction system used for forming the core.

Compared with the core component, the fundamental structure of the shell component has a low polarity so that the shell component has a low dielectric constant for that. However, the shell component has low mechanical strength and is likely to collapse so that it is not suited for forming pores mainly by making use of an interparticle space. As a result, the produced film has a high dielectric constant or even if it has a low dielectric constant, it tends to have very low mechanical strength. Even if the same combination of the core component and the shell component is used, balance as a whole film between dielectric constant and strength are changed, depending on the size of fine particles or thickness of the shell. The combination providing an optimum balance should be adopted as needed depending on the using purpose.

The number of silicon atoms contained in the core may be preferably greater than that contained in the shell. When the number of silicon atoms contained in the core is greater than that contained in the shell, the mechanical strength properties of the core can be exhibited effectively.

When a shell is formed on the same core, the shell may be preferably not so thick in order to achieve a low dielectric constant. For this purpose, it may be preferred to carry out, after completion of the addition of a core-forming material in a core formation step, the aging step and then start the addition of a shell-forming material. On the other hand, a shell having a certain thickness can cause a slight increase in dielectric constant, but can increase the film strength after baking because a contact area between particles widens due to deformability of the shell. When formation of a shell having a certain thickness is desired, dropwise addition of a shell-forming material may start prior to the completion of the dropwise addition of a core-forming material so as to form an intermediate layer having a gradient composition. Alternatively, an intermediate-layer-forming material may be added separately after completion of the dropwise addition of a core-forming material so as to form an intermediate layer and then, a shell may be formed as the outer layer of the resulting intermediate layer.

According to the invention, the organic silicon oxide fine particle comprising a core and a shell may consist essentially of the core and the shell, but they may comprise, between the core and the outer core, an intermediate layer having an intermediate composition between their compositions. When the organic silicon oxide fine particle comprises the intermediate layer, the proportion of the shell should be slightly heightened so that the effect on mechanical strength derived from the core may decrease a little. However, high chemical stability can be imparted to the film without drastically reducing the mechanical strength of the film itself because the contact area between particles can be widened during the film formation.

For example, it is possible to start addition of a single substance or mixture of the shell-forming hydrolyzable silane having a [C]/[Si] ratio≧1 prior to the completion of the addition of a total amount of a single substance or mixture of the core-forming hydrolyzable silane having a [C]/[Si] ratio<1. Such a method facilitates formation, between the core and the shell, of an intermediate layer having an intermediate composition between their compositions and enables to impart chemical stability to the resulting film without drastically reducing the mechanical strength of the film itself.

According to the invention, it is possible to add a total amount of a single substance or mixture of the inner-shell-forming hydrolyzable silane having a [C]/[Si] ratio<1, maintain the reaction conditions permitting progress of hydrolysis and condensation of the hydrolyzable silane, and then start the addition of a single substance or a mixture of the shell-forming hydrolyzable silane having a [C]/[Si] ratio≧1. By adding the core-forming hydrolyzable silane, carrying out the reaction sufficiently, and then adding the shell-forming hydrolyzable silane, formation of a layer having a [C]/[Si] ratio≧1 can start immediately after starting of the addition of the shell-forming raw material. This enables to form the shell having a [C]/[Si] ratio≧1 with a thinner layer.

Examples of the silane compound preferably used for the formation of the shell may include those represented by the following formulas (2), (5), (6) and (7):

R²ₙSi(OR³)₄₋ₙ (2)

R⁶ₘ(R⁷O)₃₋ₘSi—(—Y—SiR⁸_{L}(OR⁹)_{2-L})ₖ—Y—SiR¹⁰ⱼ(OR¹²)₃₋ⱼ (5)

(Z-SiR¹³ᵢ(OR⁴)₂₋ᵢ)ₕ (6)

R¹⁵_{g}-A(SiR¹⁶_{f}(OR¹⁷)_{3-f})ₑ (7)

wherein R², R³, R⁷, R⁸, R⁹, R¹⁰, R¹¹, R¹², R¹³, R¹⁴, R¹⁵, R¹⁶ and R¹⁷ each independently represents a C₁₋₆ hydrocarbon group, Y and Z each independently represents an oxygen atom, a C₁₋₆ alkylene chain or a divalent aromatic group which may have a substituent (for example, an alkyl group or a fluoroalkyl group), m and j each stands for an integer from 0 to 2, L and i each stands for an integer from 1 to 2, k stands for an integer from 0 to 20, h stands for an integer from 3 to 6, g stands for an integer from 0 to 4, f stands for an integer from 0 to 2, and e stands for an integer from 2 to 6.

As the hydrolyzable silane represented by the formula (2), the above exemplified ones that can be added secondarily upon formation of the core can be used.

Specific examples of the skeleton of the hydrolyzable silane represented by the formula (5) are shown below.

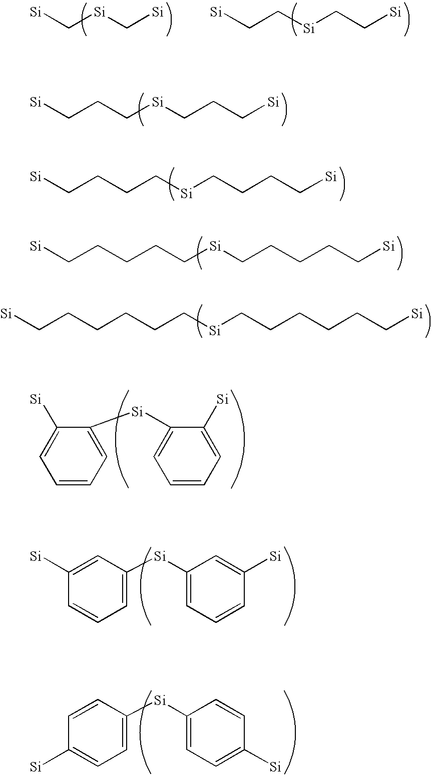

Specific examples of the hydrolyzable silane represented by the formula (5) may include linear siloxane such as 1,3-dimethyl-1,1,3,3-tetramethoxydisiloxane, 1,1,3-trimethyl-1,3,3-trimethoxydisiloxane, 1,1,3,3-tetramethyl-1,3-dimethoxydisiloxane, 1,3-dimethyl-1,1,3,3-tetraethoxydisiloxane, 1,1,3-trimethyl-1,3,3-triethoxydisiloxane, 1,1,3,3-tetramethyl-1,3-diethoxydisiloxane, 1,3-dimethyl-1,1,3,3-tetrapropoxydisiloxane, 1,1,3-trimethyl-1,3,3-tripropoxydisiloxane, 1,1,3,3-tetramethyl-1,3-dipropoxydisiloxane, 1,3-dimethyl-1,1,3,3-tetrabutoxydisiloxane, 1,1,3-trimethyl-1,3,3-tributoxydisiloxane, 1,1,3,3-tetramethyl-1,3-dibutoxydisiloxane, 1,3,5-trimethyl-1,1,3,5,5-pentamethoxytrisiloxane, 1,1,3,5-tetramethyl-1,3,5,5-tetramethoxytrisiloxane, 1,1,3,5,5-pentamethyl-1,3,5-trimethoxytrisiloxane, 1,3,5-trimethyl-1,1,3,5,5-pentaethoxytrisiloxane, 1,1,3,5-tetramethyl-1,3,5,5-tetraethoxytrisiloxane, 1,1,3,5,5-pentamethyl-1,3,5-triethoxytrisiloxane, 1,3,5,7-tetramethyl-1,1,3,5,7,7-hexamethoxytetrasiloxane, 1,1,3,5,7,7-hexamethyl-1,3,5,7-tetramethoxytetrasiloxane, 1,3,5,7-teteramethyl-1,1,3,5,7,7-hexaethoxytetrasiloxane and 1,1,3,5,7,7-hexamethyl-1,3,5,7-tetraethoxytetrasiloxane. Additional examples may include bis(trimethoxysilyl)methane, bis(triethoxysilyl)methane, bis(methyldimethoxysilyl)methane, bis(methyldiethoxysilyl)methane, bis(dimethylmethoxysilyl)methane, bis(dimethylethoxysilyl)methane, 1,2-bis(trimethoxysilyl)ethane, 1,2-bis(triethoxysilyl)ethane, 1,2-bis(methyldimethoxysilyl)ethane, 1,2-bis(methyldiethoxysilyl)ethane, 1,2-bis(dimethylmethoxysilyl)ethane, 1,2-bis(dimethylethoxysilyl)ethane, 1,3-bis(trimethoxysilyl)propane, 1,3-bis(triethoxysilyl)propane, 1,3-bis(methyldimethoxysilyl)propane, 1,3-bis(methyldiethoxysilyl)propane, 1,3-bis(dimethylmethoxysilyl)propane, 1,3-bis(dimethylethoxysilyl)propane, 1,4-bis(trimethoxysilyl)butane, 1,4-bis(triethoxysilyl)butane, 1,4-bis(methyldimethoxysilyl)butane, 1,4-bis(methyldiethoxysilyl)butane, 1,4-bis(dimethylmethoxysilyl)butane, 1,4-bis(dimethylethoxysilyl)butane, 1,5-bis(trimethoxysilyl)pentane, 1,5-bis(triethoxysilyl)pentane, 1,5-bis(methyldimethoxysilyl)pentane, 1,5-bis(methyldiethoxysilyl)pentane, 1,5-bis(dimethylmethoxysilyl)pentane, 1,5-bis(dimethylethoxysilyl)hexane, 1,6-bis(trimethoxysilyl)hexane, 1,6-bis(triethoxysilyl)hexane, 1,6-bis(methyldimethoxysilyl)hexane, 1,6-bis(methyldiethoxysilyl)hexane, 1,6-bis(dimethylmethoxysilyl)hexane, 1,6-bis(dimethylethoxysilyl)hexane, 1,2-bis(trimethoxysilyl)benzene, 1,2-bis(triethoxysilyl)ethane, 1,2-bis(methyldimethoxysilyl)benzene, 1,2-bis(methyldiethoxysilyl)benzene, 1,2-bis(dimethylmethoxysilyl)benzene, 1,2-bis(dimethylethoxysilyl)benzene, 1,3-bis(triimethoxysilyl)benzene, 1,3-bis(triethoxysilyl)ethane, 1,3-bis(methyldimethoxysilyl)benzene, 1,3-bis(methyldiethoxysilyl)benzene, 1,3-bis(dimethylmethoxysilyl)benzene, 1,3-bis(dimethylethoxysilyl)benzene, 1,4-bis(trimethoxysilyl)benzene, 1,4-bis(triethoxysilyl)ethane, 1,4-bis(methyldimethoxysilyl)benzene, 1,4-bis(methyldiethoxysilyl)benzene, 1,4-bis(dimethylmethoxysilyl)benzene, and 1,4-bis(dimethylethoxysilyl)benzene.

These compounds have a crosslinking group at both ends of the unit thereof and a flexible structure at an intermediate portion thereof so that they can be easily structured and therefore have an improved film formation property compared with a simple silane compound. In particular, when a compound has the intermediate component attached via an alkylene chain or phenylene chain, such a compound can form a shell having higher hydrophobicity compared with a hydrolysis condensate of a compound having a siloxane bond or a silane compound.

The following are specific examples of the skeleton of the hydrolyzable silane represented by the formula (6).

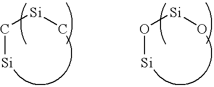

Specific examples of the hydrolyzable silane represented by the formula (6) may include 1,3,5-trimethyl-1,3,5-trimethoxycyclotrisiloxane, 1,3,5-trimethyl-1,3,5-triethoxycyclotrisiloxane, 1,3,5-trimethyl-1,3,5-tripropoxycyclotrisiloxane, 1,3,5-trimethyl-1,3,5-tributoxycyclotrisiloxane, 1,3,5,7-tetramethyl-1,3,5,7-tetramethoxycyclotetrasiloxane, 1,3,5,7-tetramethyl-1,3,5,7-tetraethoxycyclotetrasiloxane, 1,3,5,7-tetramethyl-1,3,5,7-tetrapropoxycyclotetrasiloxane, 1,3,5,7-tetramethyl-1,3,5,7-tetrabutoxycyclotetrasiloxane, 1,3,5-trimethyl-1,3,5-trimethoxy-1,3,5-trisilacyclohexane, 1,3,5-trimethyl-1,3,5-triethoxy-1,3,5-trisilacyclohexane, 1,3,5-trimethyl-1,3,5-tripropoxy-1,3,5-trisilacyclohexane, 1,3,5-trimethyl-1,3,5-tributoxy-1,3,5-trisilacyclohexane, 1,3,5,7-tetramethyl-1,3,5,7-tetramethoxy-1,3,5,7-tetrasilacyclooctane, 1,3,5,7-tetramethyl-1,3,5,7-tetraethoxy-1,3,5,7-tetrasilacyclooctane, 1,3,5,7-tetramethyl-1,3,5,7-tetrapropoxy-1,3,5,7-tetrasilacyclooctane and 1,3,5,7-tetramethyl-1,3,5,7-tetrabutoxy-1,3,5,7-tetrasilacyclooctane.

The following are specific examples of the skeleton of the hydrolyzable silane represented by the formula (7).

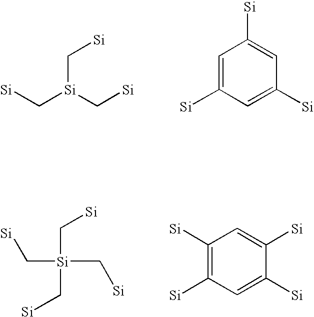

Some of the above examples of hydrolyzable silane contain an aromatic ring. Introduction of an aromatic ring is effective for improving the carbon concentration without deteriorating the heat resistance. In addition, an aromatic radical is stable similarly to a silyl radical, and Si is apt to form a bond with the aromatic so that introduction of an aromatic ring is effective for strength enhancement.

According to the invention, a shell having chemical stability owing to being imparted with hydrophobicity can be obtained by using, as the hydrolyzable silane used for the formation of the shell, a single substance or mixture of a hydrolyzable silane satisfying a [C]/[Si]≧1 wherein the [C]/[Si] is a ratio of the number of all the carbon atoms to the number of all the silicon atoms, each contained in all the groups bonded with silicon via an inherent Si—C bond.

Absence of a low stability portion is preferred in order to attain higher stability so that the single substance or mixture of the shell-forming hydrolyzable silane preferably consists essentially of hydrolyzable silane substituted with a substituent having a carbon atom directly attached to a silicon atom. The term “consist essentially of” means that 95 mol % or greater, in terms of silicon (the number of silicon atoms), more preferably 98 mol % or greater, still more preferably 100% of the silicon atoms of the hydrolysable silane may have at least one a substituent having a carbon atom directly attached to a silicon atom. This makes it possible to ensure the uniform hydrophobicity in the entire shell, prevent the formation of a portion having weak chemical stability on the surface of the shell, and impart high chemical stability to the whole particle. In other words, it is possible to prevent invasion of a nucleophilic species that acts to cut the Si—O bond from a portion having low chemical stability due to locally very high hydrophilicity.

When the shell is formed by the dropwise addition of a hydrolyzable silane compound or compounds, so-called aging time does not have be particularly long after the dropwise addition, because the silane compound or compounds react promptly after the addition, typically dropwise addition. Long aging time does not cause any marked deterioration. However, the film obtained by carrying out neutralization termination after more than 4 hours of aging after completion of the dropwise addition tends to have a reduced strength, while the film obtained by carrying out neutralization termination within one hour of aging tends to have high strength.

The minimum necessary amount of the hydrolyzable silane used for the shell can be determined by designing the thickness of the shell layer to be 0.025 nm or greater on average in order to completely cover the core with the shell layer. Under conditions for preparing silica fine particles having a particle size of 2 nm, particles are prepared while changing the molar equivalent ratio, in terms of silicon of hydrolyzable silane, of (the core-forming material)/(the shell-forming material). As a result, formation of particles which depend on the chemical properties of the shell is recognized as the portion of the shell-forming material increases from a molar equivalent ratio, in terms of silicon, of core/shell: 90/10. Assuming that the core and the shell have the same density, the minimum necessary thickness of the shell layer is estimated at 0.025 nm. When the amounts of hydrolyzable silane compounds used for the core and shell are compared in terms of silicon atoms, it is preferred to use the hydrolyzable silane compound for the shell in an amount not greater than the molar equivalent number of the hydrolyzable silane compound or compounds used for the core. When the molar equivalent number of the silane compound or compounds used for the shell exceeds that of the silane compound or compounds used for the core, there may be a danger of the high mechanical strength of the core not being reflected sufficiently in the physical property of the entire silica fine particles. The hydrolyzable silane compounds may be used for the core and the shell at a molar equivalent ratio of from 90/10 to 50/50 when the fine particles have an average particle size of about 2 nm.

When the hydrolysis and condensation reaction of the silane compound or compounds for formation of the shell is completed, a step of protecting a surface active silanol may be preferably introduced. More specifically, after neutralization reaction of the basic catalyst and prior to disappearance of crosslinking activity, more preferably immediately after the neutralization reaction, a divalent or higher valent carboxylic acid compound may be added to protect the active silanol. Alternatively, the neutralization reaction itself may be performed with a divalent or higher valent carboxylic acid to simultaneously carry out neutralization and silanol protection. Thus, the crosslinking activity can be frozen until the carboxylic acid compound decomposes at the time of film formation.

Examples of the preferable carboxylic acid having at least two carboxyl groups in the molecule thereof may include oxalic acid, malonic acid, malonic anhydride, maleic acid, maleic anhydride, fumaric acid, glutaric acid, glutaric anhydride, citraconic acid, citraconic anhydride, itaconic acid, itaconic anhydride and adipic acid. The carboxylic acid may act effectively when added in an amount of preferably from 0.05 to 10 mol %, more preferably from 0.5 to 5 mol %, each based on the molar amount of the silane compound or compounds.

A film-forming composition using the organic silicon oxide fine particle of the invention can be prepared in accordance with the conventional preparation method (for example, JP 2005-216895A or JP 2004-161535A) of a film-forming composition containing an organic silicon oxide fine particle.

When the film-forming composition is used as a semiconductor insulating film material described later and alkali metal hydroxide is used as the hydrophilic basic catalyst, demetallization treatment is inevitably performed in any stage of from the above reaction termination to the preparation of a coating composition solution. Although there are many examples of the demetallization treatment, a method using an ion exchange resin or water-washing of an organic solvent solution is typically employed. Such demetallization treatment is not essential when a silica sol is prepared using a combination of only ammonium catalysts not containing a metal impurity, but it is the common practice to add a demetallization treatment step similarly.

In addition, a solvent such as water used for preparing a solution containing the organic silicon oxide fine particles is usually replaced by a solvent for coating composition described later. There are many known examples of this method. Even in the case where the organic silicon oxide fine particles of the invention have been subjected to the above stabilization treatment, it may be not preferred to remove the solvent completely to isolate these particles.

Many solvents are known as a solvent to be used for preparing a solution of a film-forming coating composition and these solvents can be used for the film-forming composition of the invention. Specific examples may include an aliphatic hydrocarbon solvent such as n-pentane, isopentane, n-hexane, isohexane, n-heptane, 2,2,2-trimethylpentane, n-octane, isooctane, cyclohexane and methylcyclohexane; an aromatic hydrocarbon solvent such as benzene, toluene, xylene, ethylbenzene, trimethylbenzene, methylethylbenzene, n-propylbenzene, isopropylbenzene, diethylbenzene, isobutylbenzene, triethylbenzene, diisopropylbenzene and n-amylnaphthalene; a ketone solvent such as acetone, methyl ethyl ketone, methyl n-propyl ketone, methyl n-butyl ketone, methyl isobutyl ketone, cyclohexanone, 2-hexanone, methylcyclohexanone, 2,4-pentanedione, acetonylacetone, diacetone alcohol, acetophenone and fenthion; an ether solvent such as ethyl ether, isopropyl ether, n-butyl ether, n-hexyl ether, 2-ethylhexyl ether, dioxolane, 4-methyldioxolane, dioxane, dimethyldioxane, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol dimethyl ether, diethylene glycol monoethyl ether, diethylene glycol diethyl ether, diethylene glycol monopropyl ether, diethylene glycol dipropyl ether, diethylene glycol monobutyl ether, diethylene glycol dibutyl ether, tetrahydrofuran, 2-methyltetrahydrofuran, propylene glycol monomethyl ether, propylene glycol dimethyl ether, propylene glycol monoethyl ether, propylene glycol diethyl ether; propylene glycol monopropyl ether, propylene glycol dipropyl ether, propylene glycol monobutyl ether, dipropylene glycol dimethyl ether, dipropylene glycol diethyl ether, dipropylene glycol dipropyl ether, and dipropylene glycol dibutyl ether; an ester solvent such as diethyl carbonate, ethyl acetate, γ-butyrolactone, γ-valerolactone, n-propyl acetate, isopropyl acetate, n-butyl acetate, isobutyl acetate, sec-butyl acetate, n-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, dipropylene glycol monomethyl ether acetate, dipropylene glycol monoethyl ether acetate, dipropylene glycol mono-n-butyl ether acetate, glycol diacetate, methoxytriglycol acetate, ethyl propionate, n-butyl propionate, isoamyl propionate, diethyl oxalate, di-n-butyl oxalate, methyl lactate, ethyl lactate, n-butyl lactate, n-amyl lactate, diethyl malonate, dimethyl phthalate and diethyl phthalate; a nitrogen-containing solvent such as N-methylformamide, N,N-dimethylformamide, acetamide, N-methylacetamide, N,N-dimethylacetamide, N-methylpropionamide and N-methylpyrrolidone; and a sulfur-containing solvent such as dimethyl sulfide, diethyl sulfide, thiophene, tetrahydrothiophene, dimethyl sulfoxide, sulfolane and 1,3-propanesultone.

These solvents may be used singly or in combination.

In some cases, a coating solution can be prepared by mixing a micelle-forming compound such as polyether or long-chain alkyltrimethylammonium salt, or a heat-decomposable compound for simply forming pores. Examples of the heat-decomposable compound may preferably include sugars, polyacrylate, polymethacrylate and hydrocarbon compounds having a boiling point of from 250 to 400° C.

Dilution can be finally performed to prepare a composition for obtaining a desired film. The degree of dilution may differ depending on the viscosity, intended film thickness or the like. Dilution may be typically performed so that the solvent in the film composition is preferably from 50 to 99% by weight, more preferably from 75 to 98% by weight.

As a material which can be added to a film-forming composition, many film-forming auxiliary components including a surfactant are known and any of them can fundamentally be used for the film-forming composition of the invention.

The film-forming composition of the present invention may contain, as the silicon polymer component, a polysiloxane prepared by the other method. In order to achieve the advantage of the invention, the ratio of the polysiloxane prepared by the other method may be preferably 50% by weight or less, more preferably 20% by weight or less based on the weight of the organic silicon oxide fine particle comprising at least a core and a shell.

A film having any thickness can be formed by preparing a porous film-forming composition in the above manner and then applying it to a substrate preferably by spin coating, while controlling the concentration of the solute of the porous film-forming composition and employing an adequate rotation number.

The actual film thickness may be, but not limited to, typically from about 0.1 to 1.0 μm. A film having a greater thickness can also be formed by application in a plurality of times.

The composition can be applied by not only spin coating but also another method such as scan coating.

The film thus formed can be made porous by a known method. For example, a porous film can be obtained by removing the solvent by heating the film in an oven or like in a drying step (usually a step called “prebake” in a semiconductor process), preferably heating it to from 50 to 150° C. for several minutes and then baking at from 350 to 450° C. for from 1 to 60 minutes. The heating step (baking step) may be followed by an additional step such as a curing step using an ultraviolet ray or electron beam. The heating step (baking step) may be replaced by a step of exposing to an electron beam or light. Exposure to an electron beam or light enables to efficiently increase the Si—O—Si bond and achieve higher strength.

### EXAMPLES

### Synthesis Example 1

A mixture of 8.26 g of a 25% by weight aqueous solution of tetramethylammonium hydroxide, 34.97 g of ultrapure water, and 376.80 g of ethanol was heated to 60° C. in advance. A mixture of 19.48 g of tetramethoxysilane and 17.44 g of methyltrimethoxysilane was added dropwise thereto over 1 hour. Immediately after completion of the dropwise addition, a mixture of 4.33 g of 1,2-bis(trimethoxysilyl)ethane and 4.36 g of methyltrimethoxysilane was added dropwise to the reaction mixture over 15 minutes without changing the conditions. After completion of the dropwise addition, the reaction mixture was cooled to 40° C. or less and neutralized with an aqueous solution of maleic acid. After addition of 150 g of propylene glycol propyl ether, the resulting mixture was concentrated at a temperature not greater than 40° C. under a reduced pressure to distill off ethanol. Ethyl acetate (300 ml) was added, followed by washing three times with 200 ml of ultrapure water. Propylene glycol propyl ether (200 ml) was added and the resulting mixture was re-concentrated at a temperature not greater than 40° C. under a reduced pressure. The solution thus obtained was filtered through a 0.05 μm filter to obtain Coating Solution 1.

### Synthesis Example 2

As in Synthesis Example 1, a mixture of 8.26 g of a 25% by weight aqueous solution of tetramethylammonium hydroxide, 34.97 g of ultrapure water and 376.80 g of ethanol was heated to 60° C. in advance. A mixture of 17.05 g of tetramethoxysilane and 15.26 g of methyltrimethoxysilane was added dropwise over 53 minutes, followed by the dropwise addition of a mixture of 6.49 g of 1,2-bis(trimethoxysilyl)ethane and 6.54 g of methyltrimethoxysilane over 22 minutes. Neutralization, concentration, washing with water, re-concentration and filtration were performed in a similar manner to those of Synthesis Example 1 to obtain Coating Solution 2.

### Synthesis Example 3

As in Synthesis Example 1, a mixture of 8.26 g of a 25% by weight aqueous solution of tetramethylammonium hydroxide, 34.97 g of ultrapure water and 376.80 g of ethanol was heated to 60° C. in advance. A mixture of 21.92 g of tetramethoxysilane and 16.92 g of methyltrimethoxysilane was added dropwise over 68 minutes, followed by the dropwise addition of a mixture of 2.16 g of 1,2-bis(trimethoxysilyl)ethane and 2.20 g of methyltrimethoxysilane over 8 minutes. Neutralization, concentration, washing with water, re-concentration and filtration were performed in a similar manner to those of Synthesis Example 1 to obtain Coating Solution 3.

### Synthesis Example 4

As in Synthesis Example 1, a mixture of 8.26 g of a 25% by weight aqueous solution of tetramethylammonium hydroxide, 34.97 g of ultrapure water and 376.80 g of ethanol was heated to 60° C. in advance. A mixture of 19.48 g of tetramethoxysilane and 17.44 g of methyltrimethoxysilane was added dropwise over one hour, followed by the dropwise addition of a mixture of 5.10 g of 1,4-bis(trimethoxysilyl)benzene and 4.36 g of methyltrimethoxysilane over 15 minutes. Neutralization, concentration, washing with water, re-concentration and filtration were performed in a similar manner to those of Synthesis Example 1 to obtain Coating Solution 4.

### Synthesis Example 5

### Silicon Oxide Derivative Obtained by Employing Intermediate Aging After Preparation of a Core

As in Synthesis Example 1, a mixture of 8.26 g of a 25% by weight aqueous solution of tetramethylammonium hydroxide, 34.97 g of ultrapure water, and 376.80 g of ethanol was heated to 60° C. in advance. A mixture of 19.48 g of tetramethoxysilane and 17.44 g of methyltrimethoxysilane was added dropwise over one hour. After completion of the dropwise addition, the reaction mixture was aged for one hour without changing the temperature. Then, a mixture of 4.33 g of 1,2-bis(trimethoxysilyl)ethane and 4.36 g of methyltrimethoxysilane was added dropwise over 15 minutes. Neutralization, concentration, washing with water, re-concentration and filtration were performed in a similar manner to those of Synthesis Example 1 to obtain Coating Solution 5.

### Synthesis Example 6

### Silicon Oxide Derivative Comprising an Intermediate Layer

As in Synthesis Example 1, a mixture of 8.26 g of a 25% by weight aqueous solution of tetramethylammonium hydroxide, 34.97 g of ultrapure water and 376.80 g of ethanol was heated to 60° C. in advance. A mixture of 17.05 g of tetramethoxysilane and 15.26 g of methyltrimethoxysilane was added dropwise over 60 minutes. The dropwise addition rate was reduced by half after 45 minutes passed since the dropwise addition was started, and at the same time, the dropwise addition of a mixture of 6.49 g of 1,2-bis(trimethoxysilyl)ethane and 6.54 g of methyltrimethoxysilane was started. When the dropwise addition of teramethoxysilane and methyltrimethoxysilane was completed after 15 minutes, the dropwise addition rate was doubled and they were added dropwise over 30 minutes in total. Then, neutralization, concentration, washing with water, re-concentration, and filtration were performed in a similar manner to those of Synthesis Example 1 to obtain Coating Solution 6.

### Comparative Synthesis Example 1

As in Synthesis Example 1, a mixture of 8.26 g of a 25% by weight aqueous solution of tetramethylammonium hydroxide, 34.97 g of ultrapure water and 376.80 g of ethanol was heated to 60° C. in advance. A mixture of 24.36 g of tetramethoxysilane and 21.80 g of methyltrimethoxysilane was added dropwise over 1 hour. Neutralization, concentration, washing with water, re-concentration and filtration were performed in a similar manner to those of Synthesis Example 1 to obtain Coating Solution 7.

### Comparative Synthesis Example 2

As in Synthesis Example 1, a mixture of 8.26 g of a 25% aqueous solution of tetramethylammonium hydroxide, 34.97 g of ultrapure water and 376.80 g of ethanol was heated to 60° C. in advance. A mixture of 21.63 g of 1,2-bis(trimethoxysilyl)ethane and 21.80 g of methyltrimethoxysilane was added dropwise over 1 hour. Neutralization, concentration, washing with water, re-concentration and filtration were performed in a similar manner to those of Synthesis Example 1 to obtain Coating Solution 8.

### Examples 1 to 6 and Comparative Examples 1 and 2

Each of Coating Solutions 1 to 6 (Examples 1 to 6) and Coating Solutions 7 and 8 (Comparative Examples 1 and 2) was applied to a Si wafer by spin coating. After soft baking at 120° C. for 2 minutes and at 200° C. for 2 minutes, the resulting wafer was baked at 400° C. for 1 hour in a baking furnace.

The dielectric constant of the porous films thus obtained was measured before washing (initial) and after washing of the porous films. The washing treatment of the porous films was performed by dipping the porous films in EKC520 (trade mark; product of Dupont) at room temperature for 10 minutes. The dielectric constant was measured in accordance with CV process using an automatic mercury probe by using “495-CV System” (trade name; product of SSM Japan). The elastic modulus (modulus) was measured using a nanoindenter (product of Nano Instruments). The results are shown in Table 1.

TABLE 1

| | |
|---|---|
| Initial | after washing |

| | | modulus | | modulus |
|---|---|---|---|---|
| | k-value | (GPa) | k-value | (GPa) |
| Example 1 | 2.43 | 6.9 | 2.45 | 6.6 |
| Example 2 | 2.39 | 6.6 | 2.41 | 6.4 |
| Example 3 | 2.48 | 7.0 | 2.52 | 6.7 |
| Example 4 | 2.41 | 6.7 | 2.43 | 6.5 |
| Example 5 | 2.28 | 5.8 | 2.32 | 5.6 |
| Example 6 | 2.41 | 6.6 | 2.44 | 6.4 |
| Comp. Ex. 1 | 2.51 | 7.2 | 2.78 | 4.8 |
| Comp. Ex. 2 | 2.29 | 3.4 | 2.30 | 3.4 |

The porous films obtained in Examples 1 to 6 have improved strength reflecting the strength of a core component in the initial values of the properties compared with the porous film obtained in Comparative Example 2 not having a high Si—O bond density. With regard to the properties after washing with a washing fluid, the porous films obtained in Examples 1 to 6 have reduced deterioration reflecting the stability of the shell component compared with the porous film of Comparative Example 1 not having an outer shall with a high C/Si ratio.

Having thus described certain embodiments of the present invention, it is to be understood that the invention defined by the appended claims is not to be limited by particular details set forth in the above description as many apparent variations thereof are possible without departing from the spirit or scope thereof as hereinafter claimed. The following claims are provided to ensure that the present application meets all statutory requirements as a priority application in all jurisdictions and shall not be construed as setting forth the full scope of the present invention.

1. An organic silicon oxide fine particle comprising:
a core comprising an inorganic silicon oxide or a first organic silicon oxide containing an organic group having a carbon group directly attached to a silicon atom, and
a shell on or above an outer circumference of the core, the shell comprising a second organic silicon oxide different from the first organic silicon oxide which the second organic silicon oxide has been formed by hydrolysis and condensation of a shell-forming component comprising an organic-group-containing hydrolyzable silane containing an organic group having a carbon atom attached directly to a silicon atom or a mixture of the organic-group-containing hydrolyzable silane and an organic-group-free hydrolyzable silane not containing the organic group in the presence of a basic catalyst,
wherein a ratio of [C]/[Si] is 0 or greater but less than 1 in the core and 1 or greater in the shell wherein [C] represents the total number of carbon atoms contained by the organic group of the first organic silicon oxide in the core or by the organic group of the second organic silicon oxide in the shell and [Si] represents the total number of silicon atoms contained in the core or in the shell.

2. The organic silicon oxide fine particle according to claim 1, wherein said number of silicon atoms contained by the core is greater than said number of silicon atoms contained by the shell.

3. The organic silicon oxide fine particle according to claim 1, wherein said core has been formed by hydrolysis and condensation of, in the presence of a basic catalyst, a core-forming component comprising an organic-group-containing hydrolyzable silane containing an organic group having a carbon atom directly attached to a silicon atom and/or an organic-group-free hydrolyzable silane not containing the organic group.

4. The organic silicon oxide fine particle according to claim 1, further comprising an intermediate layer between the core and the shell.

5. The organic silicon oxide fine particle according to claim 1, wherein said shell-forming component consists essentially of the organic-group-containing hydrolyzable silane.

6. A method for preparing an organic silicon oxide fine particle, comprising steps of:
hydrolyzing and condensing, in the presence of a basic catalyst and in water or a mixed solution of water and alcohol, a core-forming component comprising a first organic-group-containing hydrolyzable silane containing an organic group having a carbon atom directly attached to a silicon atom or a first organic-group-free hydrolyzable silane not containing the organic group to form a core,
wherein the core-forming component has a [C]/[Si] ratio of 0 or greater but less than 1 wherein [C] represents the number of all the carbon atoms contained by the organic group and [Si] represents the number of all the silicon atoms contained by the core-forming component; and
adding, to the reaction mixture thus obtained, a shell-forming component comprising a second organic-group-containing hydrolyzable silane containing an organic group having a carbon atom directly attached to a silicon atom or a mixture of the second organic-group-containing hydrolyzable silane and a second organic-group-free hydrolyzable silane to form a shell,
wherein the shell-forming component has a [C]/[Si] ratio of 1 or greater, wherein [C] represents the number of all the carbon atoms contained by the organic group of the second organic-group-containing hydrolyzable silane and [Si] represents the number of all the silicon atoms contained by the shell-forming component.

7. The method for preparing an organic silicon oxide fine particle according to claim 6, wherein after addition of a total amount of the core-forming component, a reaction condition for progress of hydrolyzing and condensing the core-forming component is maintained and then the step of adding the shell-forming component starts.

8. The method for preparing an organic silicon oxide fine particle according to claim 6, wherein prior to completion of addition of a total amount of the core-forming component, the step of adding the shell-forming component starts.

9. A porous film-forming composition, comprising at least the organic silicon oxide fine particle as claimed in claim 1 and an organic solvent.

10. A porous film formed by using the porous film-forming composition as claimed in claim 9.

11. A method for forming a porous film, comprising steps of:
applying the porous film-forming composition as claimed in claim 9 to form a film and
subjecting the film to heat, or an electron beam or light.

12. The method for forming a porous film according to claim 11, wherein the step of subjecting comprises subjecting to heat and then subjecting to an electron beam or light.

13. A semiconductor device, comprising the porous film as claimed in claim 10 as an insulating film.
